(19) United States
(12) Patent Application Publication
(10) Pub. No.: US 2016/0329515 A1
(43) Pub. Date: Nov. 10, 2016

(54) ORGANIC LIGHT-EMITTING COMPONENT AND METHOD FOR PRODUCING AN ORGANIC LIGHT-EMITTING COMPONENT

(71) Applicant: OSRAM OLED GmbH, Regensburg (DE)

(72) Inventors: Arne Fleissner, Regensburg (DE); Marc Philippens, Regensburg (DE)

(21) Appl. No.: 15/110,126

(22) PCT Filed: Jan. 15, 2015
(86) PCT No.: PCT/EP2015/050644

§ 371 Date: Jul. 7, 2016

(30) Foreign Application Priority Data
Jan. 15, 2014 (DE) 10 2014 100 405.1

(51) Int. Cl. H01L 51/50; H01L 51/56

(52) U.S. Cl. CPC H01L 51/5072; H01L 51/502; H01L 51/56; H01L 51/5092; H01L 51/5088; H01L 51/5056

(57) ABSTRACT

An organic light-emitting component may include a first electrode, an organic functional layer structure over the first electrode in order to generate light, and a second electrode over the organic functional layer structure. The organic functional layer structure includes at least one layer having an organic carrier material, which has a first refractive index, and having nano-additives which are embedded in the carrier material and have a second refractive index, which is greater than the first refractive index, and which have at least one external dimension which is less than one fourth of a predetermined wavelength of the light generated. The nano-additives, the material thereof and/or a fraction thereof relative to the carrier material of the layer are selected and/or predetermined as a function of an optical path length in the organic light-emitting component or as a function of a size of a microcavity of the organic light-emitting component.

### RELATED APPLICATIONS

The present application is a national stage entry according to 35 U.S.C. §371 of PCT application No.: PCT/EP2015/050644 filed on Jan. 15, 2015, which claims priority from German application No.: 10 2014 100 405.1 filed on Jan. 15, 2014, and is incorporated herein by reference in its entirety.

### TECHNICAL FIELD

Various embodiments may relate to an organic light-emitting component and to a method for producing an organic light-emitting component.

### BACKGROUND

Organic-based optoelectronic components, for example organic light-emitting diodes (OLED) are being used increasingly widely in general lighting, for example as a flat light source. An organic light-emitting component, for example an OLED, may include an anode and a cathode with an organic functional layer system between them. The organic functional layer system may include one or more emitter layers in which electromagnetic radiation is generated, a charge carrier pair generation layer structure consisting respectively of two or more charge carrier pair generation layers (charge generating layers, CGL), and one or more electron barrier layers, also referred to as hole transport layers (HTL), and one or more hole barrier layers, also referred to as electron transport layer(s) (ETL), in order to direct the flow of current.

In high-performance OLEDs, the microcavity effect is used in order to optimize an emission spectrum and/or an efficiency of the OLED. To this end, the optical path between an emission zone of the light generated by means of the OLED and the fully or partially reflective electrodes is adjusted according to the wavelength of the light to a well-defined value. The optical path is given by the product of refractive index and thickness of the layer(s) through which the light travels.

Since the refractive index of the organic materials used in the OLED is generally predetermined, and is for example about 1.8, the optical path length is adjusted by means of the thickness of one or more organic layers of the organic layer stack. In order to achieve a sufficient optical path length for adjustment of the optimal microcavity, relatively thick organic layers are generally used. Since the organic semiconductor materials make a significant contribution to the overall OLED costs, however, this is associated with significant costs.

### SUMMARY

In various embodiments, an organic light-emitting component is provided, which can be produced simply and/or economically and/or has a small thickness and/or has an optical property precisely adjusted in a straightforward way.

In various embodiments, a method for producing an organic light-emitting component is provided, which can be carried out simply and/or economically and/or makes it possible to produce the organic light-emitting component having a small thickness, and/or makes it possible to adjust precisely an optical property of the organic light-emitting component in a straightforward way.

In various embodiments, an organic light-emitting component is provided. The organic light-emitting component includes a first electrode. An organic functional layer structure for generating light is formed over the first electrode. A second electrode is formed over the organic functional layer structure. The organic functional layer structure includes at least one layer having an organic carrier material which has a first refractive index. The layer includes nano-additives which are embedded in the carrier material and have a second refractive index, which is greater than the first refractive index. The nano-additives have at least one external dimension which is less than one fourth of a predetermined wavelength of the light generated.

By means of the layer having the carrier material and the nano-additives, it is possible to adjust optimally the optical path length as the product of refractive index and layer thickness for a microcavity of the organic light-emitting component. To this end, the refractive index of one or more layers of the organic functional layer structure is increased by adding the nano-additives having a high refractive index. The optimal optical path length for the microcavity can thus be achieved without the use of thick organic layers and with only thin organic layers. This can contribute to saving on material for the organic light-emitting component and therefore keeping the costs of the organic light-emitting component low. Furthermore, an optical path length of the generated light in the organic light-emitting component, for example from an emission zone of the light to one of the electrodes, and/or the position and/or the size of the microcavity, can be adjusted very precisely in a straightforward way.

The effective refractive index of the corresponding layer is thus increased to a value which lies between the refractive index of the carrier material and the refractive index of the material of the nanoparticles according to the volume fraction of the nano-additives in the carrier material. The carrier material is, for example, the organic material which is responsible for the function of the corresponding layer of the organic functional layer structure. The external dimension, for example the diameter and/or a side length, of the nanoparticles may be less than the thickness of the corresponding layer and/or so small that no scattering effect, or only a negligible scattering effect, with the light generated takes place. For example, the corresponding external dimension may lie for example between 0.1 nm and 20 nm, for example between 1 nm and 10 nm.

The light generated by the organic light-emitting component may for example lie in the visible spectral range, for example at wavelengths of from approximately 380 nm to approximately 780 nm. The organic light-emitting component may, however, optionally also generate electromagnetic radiation in the invisible spectral range, for example in the UV light range and/or in the infrared light range. If the organic light-emitting component generates white light, then the corresponding light spectrum may have a plurality of local maxima, in other words peaks, at different positions. If the organic light-emitting component generates monochromatic light, then the corresponding light spectrum generally has one maximum at a corresponding position, for example between approximately 420 nm and 480 nm in the case of an organic light-emitting component emitting blue light, or for example between approximately 480 nm and 560 nm in the case of an organic light-emitting component emitting green light.

In various embodiments, the predetermined wavelength is a dominant wavelength of the light generated.

In various embodiments, the predetermined wavelength is a shortest dominant wavelength or a longest dominant wavelength of the light generated. In the case of an organic light-emitting component emitting green light, the dominant wavelength may for example be 555 nm. In the case of an organic light-emitting component emitting white light, the shortest dominant wavelength may for example lie in the blue spectral range and may for example be approximately 460 nm, and/or the longest dominant wavelength may for example lie in the yellow spectral range and/or may for example be approximately 570 nm.

In various embodiments, the nano-additives include nanoparticles, nanowires, nanodots and/or nanotubes.

In various embodiments, the first refractive index lies in a range of between 1.6 and 1.8, and/or the second refractive index lies in a range of between 2.1 and 2.5.

In various embodiments, the nano-additives include TiO₂, Nb₂O₅, HfO₂, ZrO₂ and/or ZnS. For example, the nano-additives may include TiO₂ with a refractive index in a range of for example from 2.4 to 3, ZrO₂ with a refractive index of for example approximately 2.18, Nb₂O₅ with a refractive index of for example approximately 2.3, HfO₂ with a refractive index in a range of for example approximately 1.9 to approximately 2.0, ZrO₂ with a refractive index of for example approximately 2.2, or ZnS with a refractive index of for example approximately 2.37.

In various embodiments, the carrier material includes a solution-processed organic semiconductor material.

In various embodiments, the carrier material includes a polymer or soluble small molecules. The expression that the molecules are small does not necessarily refer in this context to the size of the corresponding molecules, but rather refers to a class of molecules which are generally used for organic layers of OLEDs. The corresponding OLEDs are in this context also referred to as SMOLEDs.

The use of solution-processed organic semiconductors, such as polymers or soluble small molecules, can contribute to the organic light-emitting component being producible particularly simply and/or economically. In this case, the nanoparticles may be applied from solution together with the organic material. For better processability, it is furthermore possible to use nano-additives with corresponding surface functionalization, which allows them to be soluble in the selected solvent.

In various embodiments, a hole injection layer, a hole transport layer, an electron transport layer, an emitter layer and/or an electron injection layer of the organic functional layer structure includes or is formed from the layer having the carrier material and the nano-additives. In other words, each individual or a plurality of said layers may include a carrier material corresponding to the respective function of the layer and the nano-additives for adjustment of the overall refractive index of the respective layer.

In various embodiments, the nano-additives, the material of the nano-additives, an external dimension of the nano-additives, a ratio of the nano-additives to the carrier material in the layer and/or a fraction of the nano-additives relative to the carrier material of the layer are selected and/or predetermined as a function of a predetermined optical property of the organic light-emitting component. The predetermined optical property may, for example, be an optical path length in the organic light-emitting component. For example, the predetermined optical property may be the optical path length from an emission zone of the organic functional layer structure to one of the electrodes. As an alternative or in addition, the optical property may be a size of a microcavity of the organic light-emitting component.

In various embodiments, the first electrode is formed. The organic functional layer structure is formed over the first electrode in order to generate light. The second electrode is formed over the organic functional layer structure. The organic functional layer structure is formed in such a way that it includes at least the layer having the organic carrier material, which has the first refractive index, and having nano-additives which are embedded in the carrier material and have the second refractive index, which is greater than the first refractive index, and which have at least one external dimension which is less than one fourth of the predetermined wavelength of the light generated.

In various embodiments, the carrier material is applied in the liquid state onto the first electrode, the nano-additives being dissolved or dispersed in the liquid carrier material.

The use of solution-processed organic semiconductors, such as polymers or soluble small molecules, can contribute to the organic light-emitting component being producible particularly simply and/or economically. In this case, the nanoparticles may be applied from solution together with the organic material. For better processability, it is furthermore possible to use nano-additives with corresponding surface functionalization, which allows them to be soluble in the selected solvent.

In various embodiments, the nano-additives, the material of the nano-additives, an external dimension of the nano-additives, a ratio of the nano-additives to the carrier material in the layer and/or a fraction of the nano-additives relative to the carrier material of the layer are selected and/or predetermined as a function of a predetermined optical property of the organic light-emitting component. In other words, an optical property which the organic light-emitting component is intended to have is initially specified, and the nano-additives, the material of the nano-additives, an external dimension of the nano-additives, a ratio of the nano-additives to the carrier material in the layer and/or a fraction of the nano-additives relative to the carrier material of the layer are then selected in such a way that the finished organic light-emitting component has the originally predetermined optical property.

In various embodiments, the predetermined optical property is an optical path length in the organic light-emitting component, in particular for the light generated by the organic light-emitting component.

In various embodiments, the predetermined optical property is the optical path length from an emission zone of the organic functional layer structure to one of the electrodes. The emission zone lies, for example, in an emitter layer of the OLED. For example, the emission zone lies in a middle of the emitter layer.

In various embodiments, the optical property is a size of a microcavity of the organic light-emitting component.

A microcavity is in principle formed by two e.g. semitransparent mirrors, for example by the two electrodes, and the separation and the optical medium between them, for example the organic functional layer structure. A thickness of the microcavity is dependent on the reflectivity of the corresponding mirrors. The size of the microcavity refers to the optical path length between the mirrors and determines the wavelength(s) at which the microcavity is resonant.

In particular, the microcavity is therefore formed by the two electrodes and the organic functional layer structure lying between them, the optical path length between the electrodes being adjusted correspondingly in order to adapt the microcavity according to requirements.

### BRIEF DESCRIPTION OF THE DRAWINGS

The invention is explained in greater detail below on the basis of an exemplary embodiment, wherein also as before no distinction will be drawn specifically among the claim categories and the features in the context of the independent claims are intended also to be disclosed in other combinations. In the drawings, like reference characters generally refer to the same parts throughout the different views. The drawings are not necessarily to scale, emphasis instead generally being placed upon illustrating the principles of the disclosed embodiments. In the following description, various embodiments described with reference to the following drawings, in which:

FIG. 1 shows a conventional organic light-emitting component;

FIG. 2 shows a layer structure of the conventional organic light-emitting component;

FIG. 3 shows a layer structure of an embodiment of an organic light-emitting component;

FIG. 4 shows a layer structure of an embodiment of an organic light-emitting component;

FIG. 5 shows a layer structure of an embodiment of an organic light-emitting component; and

FIG. 6 shows a flowchart of an embodiment of a method for producing an organic light-emitting component.

### DETAILED DESCRIPTION

In the following detailed description, reference is made to the appended drawings which form part of this description and in which specific embodiments in which the invention can be carried out are shown for illustration. In this regard, direction terminology such as “up”, “down”, “forward”, “backward”, “front”, “rear”, etc. is used with reference to the orientation of the figure or figures being described. Since constituent parts of embodiments can be positioned in a number of different orientations, the direction terminology is used for illustration and is in no way restrictive. It is to be understood that other embodiments may be used and structural or logical modifications may be carried out, without departing from the protective scope of the present invention. It is to be understood that the features of the various embodiments described herein may be combined with one another, unless specifically indicated otherwise. The following detailed description is therefore not to be interpreted in a restrictive sense, and the protective scope of the present invention is defined by the appended claims.

In the scope of this description, terms such as “connected” or “coupled” are used to describe both direct and indirect connection, and direct or indirect coupling. In the figures, elements which are identical or similar are provided with identical references, insofar as this is expedient.

An organic light-emitting component may in various embodiments be an organic light-emitting semiconductor component, an organic light-emitting diode and/or an organic light-emitting transistor. The organic light-emitting component may be part of an integrated circuit. Furthermore, a multiplicity of organic light-emitting components may be provided, for example fitted in a common housing.

FIG. 1 shows a conventional organic light-emitting component 1. The conventional organic light-emitting component 1 includes a carrier 12, for example a substrate. An optoelectronic layer structure is formed on the carrier 12.

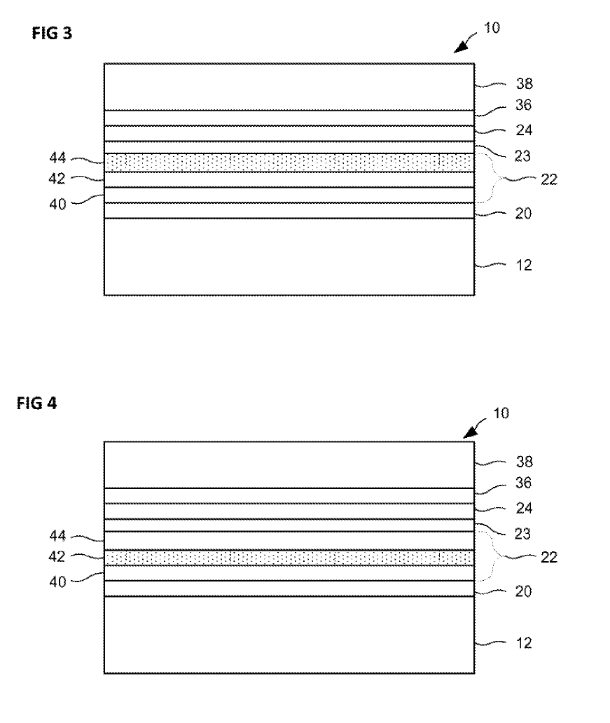

The optoelectronic layer structure includes a first electrode layer 14, which includes a first contact section 16, a second contact section 18 and a first electrode 20. The second contact section 18 is electrically coupled to the first electrode 20 of the optoelectronic layer structure. The first electrode 20 is electrically insulated from the first contact section 16 by means of an electrical insulation barrier 21. An organic functional layer structure 22 of the optoelectronic layer structure is formed over the first electrode 20. The organic functional layer structure 22 may for example include one, two or more sublayers, which will be explained in more detail below with reference to FIG. 3. A second electrode 23 of the optoelectronic layer structure, which is electrically coupled to the first contact section 16, is formed over the organic functional layer structure 22. The first electrode 20 is used, for example, as an anode or cathode of the optoelectronic layer structure. The second electrode 23 is used, in a manner corresponding to the first electrode, as a cathode or anode of the optoelectronic layer structure.

An encapsulation layer 24 of the optoelectronic layer structure, which encapsulates the optoelectronic layer structure, is formed over the second electrode 23 and partially over the first contact section 16 and partially over the second contact section 18. In the encapsulation layer 24, a first recess of the encapsulation layer 24 is formed over the first contact section 16 and a second recess of the encapsulation layer 24 is formed over the second contact section 18. A first contact region 32 is exposed in the first recess of the encapsulation layer 24, and a second contact region 34 is exposed in the second recess of the encapsulation layer 24. The first contact region 32 is used for electrical contacting of the first contact section 16, and the second contact region 34 is used for electrical contacting of the second contact section 18.

A bonding layer 36 is formed over the encapsulation layer 24. A cover body 38 is formed over the bonding layer 36. The bonding layer 36 is used for fastening the cover body 38 on the encapsulation layer 24.

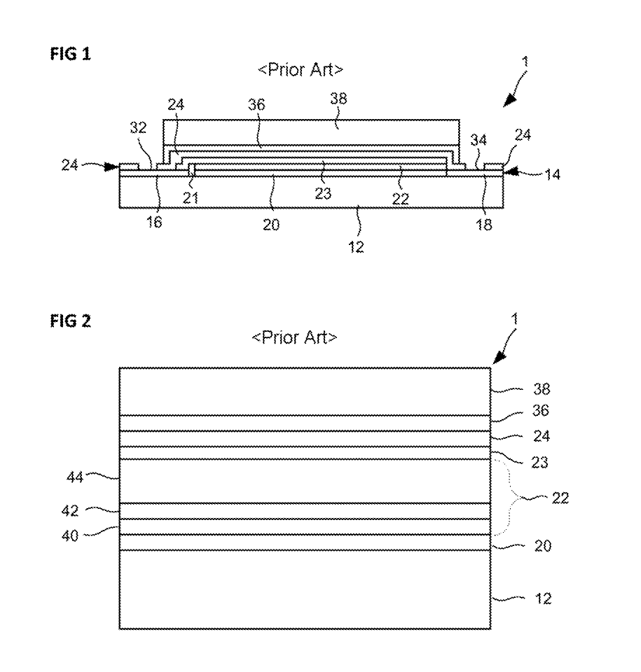

FIG. 2 shows a layer structure of a conventional organic light-emitting component, for example the organic light-emitting component 1 explained above, the contact regions 32, 34 and the contact sections 16, 18 not being represented in this view.

The organic functional layer structure 22 may include a hole transport layer 40, an emitter layer 42, an electron transport layer 44 and/or an electron injection layer (not represented) and/or a hole injection layer (not represented).

In order to adjust a microcavity of the conventional organic light-emitting component 1 and in order to adjust an optical path length between an emission zone which lies in the region of the emitter layer 42, for example in a central region of the emitter layer 42, and one of the electrodes 20, 23, the electron transport layer 44 has a large thickness.

FIG. 3 shows a detailed sectional representation of a layer structure of an embodiment of an organic light-emitting component 10, which may for example correspond substantially to the conventional organic light-emitting component 1 explained above.

The organic light-emitting component 10 may be configured as a top emitter and/or a bottom emitter. If the organic light-emitting component 10 is configured as a top emitter, then the first electrode 20 may be configured so as to be reflective. If the organic light-emitting component 10 is configured as a bottom emitter, then the second electrode 23 may be configured so as to be reflective. If the organic light-emitting component 10 is configured as a top emitter and a bottom emitter, the organic functional component 10 may be referred to as an optically transparent component, for example a transparent organic light-emitting diode.

The organic light-emitting component 10 includes the carrier 12 and an active region over the carrier 12. A first barrier layer (not represented), for example a first barrier thin film, may be formed between the carrier 12 and the active region. The active region includes the first electrode 20, the organic functional layer structure 22 and the second electrode 23. The encapsulation layer 24 is formed over the active region. The encapsulation layer 24 may be configured as a second barrier layer, for example as a second barrier thin film. The cover body 38 is arranged over the active region and optionally over the encapsulation layer 24. The cover body 38 may, for example, be arranged on the encapsulation layer 24 by means of the bonding layer 36.

The active region is an electrically and/or optically active region. The active region is, for example, the region of the organic light-emitting component 10 in which electrical current for operation of the organic light-emitting component 10 flows, and/or in which light is generated.

The organic functional layer structure 22 may include one, two or more functional layer structure units and one, two or more intermediate layers between the layer structure units. Optionally, each of the functional layer structure units may be configured according to one configuration of the organic functional layer structure 22 explained below.

The carrier 12 may be configured so as to be translucent or transparent. The carrier 12 is used as a carrier element for electronic elements or layers, for example light-emitting elements. The carrier 12 may for example include or be formed from glass, quartz and/or a semiconductor material, or any other suitable material. Furthermore, the carrier 12 may include or be formed from a plastic film or a laminate having one or more plastic films. The plastic may include one or more polyolefins. Furthermore, the plastic may include polyvinyl chloride (PVC), polystyrene (PS), polyester and/or polycarbonate (PC), polyethylene terephthalate (PET), polyether sulfone (PES) and/or polyethylene naphthalate (PEN). The carrier 12 may include or be formed from a metal, for example copper, silver, gold, platinum, iron, for example a metal compound, for example steel. The carrier 12 may be configured as a metal foil or metal-coated sheet. The carrier 12 may be a part of or form a mirror structure. The carrier 12 may include a mechanically rigid region and/or a mechanically flexible region, or be formed in such a way.

The first electrode 20 may be configured as an anode or as a cathode. The first electrode 20 may be configured so as to be translucent or transparent. The first electrode 20 includes an electrically conductive material, for example metal and/or a transparent conductive oxide (TCO) or a layer stack of a plurality of layers, which include metals or TCOs. The first electrode 20 may for example include a layer stack of a combination of a layer of a metal on a layer of a TCO, or vice versa. Examples are a silver layer which is applied onto an indium tin oxide (ITO) layer (Ag on ITO), or ITO/Ag/ITO multilayers.

For example, Ag, Pt, Au, Mg, Al, Ba, In, Ca, Sm or Li as well as compounds, combinations or alloys of these materials, may be used as the metal.

Transparent conductive oxides are transparent conductive materials, for example metal oxides, for example zinc oxide, tin oxide, cadmium oxide, titanium oxide, indium oxide or indium tin oxide (ITO). Besides binary metal-oxygen compounds, for example ZnO, SnO₂, or In₂O₃, ternary metal-oxygen compounds, for example AlZnO, Zn₂SnO₄, CdSnO₃, ZnSnO₃, MgIn₂O₄, GaInO₃, Zn₂In₂O₅ or In₄Sn₃O₁₂, or mixtures of different transparent conductive oxides, also belong to the TCO group.

As an alternative or in addition to the materials mentioned, the first electrode 20 may include: networks of metallic nanowires and nanoparticles, for example of Ag, networks of carbon nanotubes, graphene particles and graphene layers, and/or networks of semiconducting nanowires. For example, the first electrode 20 may include or be formed from one of the following structures: a network of metallic nanowires, for example of Ag, which are combined with conductive polymers, a network of carbon nanotubes which are combined with conductive polymers, and/or graphene layers and composites. Furthermore, the first electrode 20 may include electrically conductive polymers or transition metal oxides.

The first electrode 20 may for example have a layer thickness in a range of from 10 nm to 500 nm, for example from 25 nm to 250 nm, for example from 50 nm to 100 nm.

The first electrode 20 may include a first electrical terminal, to which a first electrical potential can be applied. The first electrical potential may be provided by an energy source (not represented), for example by a current source or a voltage source. As an alternative, the first electrical potential may be applied to the carrier 12 and fed indirectly to the first electrode 20 via the carrier 12. The first electrical potential may, for example, be the ground potential or another predetermined reference potential.

The organic functional layer structure 22 may include the hole transport layer 40, the emitter layer 42, the electron transport layer 44 and/or the hole injection layer (not represented) and/or the electron injection layer (not represented).

The hole injection layer may be formed on or over the first electrode 20. The hole injection layer may include or be formed from one or more of the following materials: HAT-CN, Cu(I)pFBz, MoOₓ, WOₓ, VOₓ, ReOₓ, F4-TCNQ, NDP-2, NDP-9, Bi(III)pFBz, F16CuPc; NPB (N,N′-bis(naphthalen-1-yl)-N,N′-bis(phenyl)-benzidine); beta-NPB N,N′-bis(naphthalen-2-yl)-N,N′-bis(phenyl)-benzidine); TPD (N,N′-bis(3-methylphenyl)-N,N′-bis(phenyl)-benzidine); spiro-TPD (N,N′-bis(3-methylphenyl)-N,N′-bis(phenyl)-benzidine); spiro-NPB (N,N′-bis(naphthalen-1-yl)-N,N′-bis(phenyl)-spiro); DMFL-TPD N,N′-bis(3-methylphenyl)-N,N′-bis(phenyl)-9,9-dimethyl-fluorene); DMFL-NPB (N,N′-bis(naphthalen-1-yl)-N,N′-bis(phenyl)-9,9-dimethyl-fluorene); DPFL-TPD (N,N′-bis(3-methylphenyl)-N,N′-bis(phenyl)-9,9-diphenyl-fluorene); DPFL-NPB (N,N′-bis(naphthalen-1-yl)-N,N′-bis(phenyl)-9,9-diphenyl-fluorene); spiro-TAD (2,2′,7,7′-tetrakis(n,n-diphenylamino)-9,9′-spirobifluorene); 9,9-bis[4-(N,N-bis-biphenyl-4-yl-amino)phenyl]-9H-fluorine; 9,9-bis[4-(N,N-bis-naphthalen-2-yl-amino)phenyl]-9H-fluorene; 9,9-bis[4-(N,N′-bis-naphthalen-2-yl-N,N′-bis-phenyl-amino)-phenyl]-9H-fluorine; N,N′ bis(phenanthren-9-yl)-N,N′-bis(phenyl)-benzidine; 2,7 bis[N,N-bis(9,9-spiro-bifluorene-2-yl)-amino]-9,9-spiro-bifluorene; 2,2′-bis[N,N-bis(biphenyl-4-yl)amino]9,9-spiro-bifluorene; 2,2′-bis(N,N-di-phenyl-amino)9,9-spiro-bifluorene; di-[4-(N,N-ditolyl-amino)-phenyl]cyclohexane; 2,2′,7,7′-tetra(N,N-di-tolyl)amino-spiro-bifluorene; and/or N,N,N′,N′-tetra-naphthalen-2-yl-benzidine.

The hole injection layer may have a layer thickness in a range of from approximately 10 nm to approximately 1000 nm, for example in a range of from approximately 30 nm to approximately 300 nm, for example in a range of from approximately 50 nm to approximately 200 nm.

The hole transport layer 40 may be formed on or over the hole injection layer. The hole transport layer 40 may include or be formed from one or more of the following materials: NPB (N,N′-bis(naphthalen-1-yl)-N,N′-bis(phenyl)-benzidine); beta-NPB N,N′-bis(naphthalen-2-yl)-N,N′-bis(phenyl)-benzidine); TPD (N,N′-bis(3-methylphenyl)-N,N′-bis(phenyl)-benzidine); spiro-TPD (N,N′-bis(3-methylphenyl)-N,N′-bis(phenyl)-benzidine); spiro-NPB (N,N′-bis(naphthalen-1-yl)-N,N′-bis(phenyl)-spiro); DMFL-TPD N,N′-bis(3-methylphenyl)-N,N′-bis(phenyl)-9,9-dimethyl-fluorene); DMFL-NPB (N,N′-bis(naphthalen-1-yl)-N,N′-bis(phenyl)-9,9-dimethyl-fluorene); DPFL-TPD (N,N′-bis(3-methylphenyl)-N,N′-bis(phenyl)-9,9-diphenyl-fluorene); DPFL-NPB (N,N′-bis(naphthalen-1-yl)-N,N′-bis(phenyl)-9,9-diphenyl-fluorene); spiro-TAD (2,2′,7,7′-tetrakis(n,n-diphenylamino)-9,9′-spirobifluorene); 9,9-bis[4-(N,N-bis-biphenyl-4-yl-amino)phenyl]-9H-fluorene; 9,9-bis[4-(N,N-bis-naphthalen-2-yl-amino)phenyl]-9H-fluorene; 9,9-bis[4-(N,N′-bis-naphthalen-2-yl-N,N′-bis-phenyl-amino)-phenyl]-9H-fluorine; N,N′ bis(phenanthren-9-yl)-N,N′-bis(phenyl)-benzidine; 2,7-bis[N,N-bis(9,9-spiro-bifluorene-2-yl)-amino]-9,9-spiro-bifluorene; 2,2′-bis[N,N-bis(biphenyl-4-yl)amino]9,9-spiro-bifluorene; 2,2′-bis(N,N-diphenyl-amino)9,9-spiro-bifluorene; di-[4-(N,N-ditolyl-amino)-phenyl]cyclohexane; 2,2′,7,7′-tetra(N,N-di-tolyl)amino-spiro-bifluorene; and N,N,N′,N′ tetra-naphthalen-2-yl-benzidine.

The hole transport layer 40 may have a layer thickness in a range of from approximately 5 nm to approximately 50 nm, for example in a range of from approximately 10 nm to approximately 30 nm, for example approximately 20 nm.

The one or more emitter layers 42, for example having fluorescent and/or phosphorescent emitters, may be formed on or over the hole transport layer 40. The emitter layer 42 may include organic polymers, organic oligomers, organic monomers, nonpolymeric organic small molecules, or a combination of these materials. The emitter layer 42 may include or be formed from one or more of the following materials: organic or organometallic compounds such as derivatives of polyfluorene, polythiophene and polyphenylene (for example 2- or 2,5-substituted poly-p-phenylene vinylene), as well as metal complexes, for example iridium complexes such as blue phosphorescent FIrPic (bis(3,5-difluoro-2-(2-pyridyl)phenyl-(2-carboxypyridyl)-iridium III), green phosphorescent Ir(ppy)₃ (tris(2-phenylpyridine)iridium III), red phosphorescent Ru(dtb-bpy)₃*2(PF₆) (tris[4,4′-di-tert-butyl-(2,2′)-bipyridine]ruthenium(III) complex) and blue fluorescent DPAVBi (4,4-bis[4-(di-p-tolylamino)styryl]biphenyl), green fluorescent TTPA (9,10-bis[N,N-di-(p-tolyl)-amino]anthracene) and red fluorescent DCM2 (4-dicyanomethylene)-2-methyl-6-julolidyl-9-enyl-4H-pyrane) as nonpolymeric emitters. Such nonpolymeric emitters may, for example, be deposited by means of thermal evaporation. Polymer emitters may furthermore be used, which may for example be deposited by means of a wet chemical method, for example a spin coating method. The emitter materials may be embedded in a suitable way in a matrix material, for example a technical ceramic or a polymer, for example an epoxide, or a silicone.

The first emitter layer 42 may have a layer thickness in a range of from approximately 5 nm to approximately 50 nm, for example in a range of from approximately 10 nm to approximately 30 nm, for example approximately 20 nm.

The emitter layer 42 may include emitter materials emitting in one color or different colors (for example blue and yellow or blue, green and red). As an alternative, the emitter layer 42 may include a plurality of sublayers which emit light of different colors. Mixing of the different colors may lead to the emission of light with a white color impression. As an alternative or in addition, a converter material may be arranged in the beam path of the primary emission generated by these layers, which material at least partially absorbs the primary radiation and emits secondary radiation with a different wavelength, so that for example a white color impression is obtained from (not yet white) primary radiation by the combination of primary radiation and secondary radiation.

The electron transport layer 44 may be formed, for example deposited, on or over the emitter layer 42. The electron transport layer 44 includes a carrier material and nano-additives embedded in the carrier material.

The carrier material has a first refractive index, for example a first refractive index in a range of between for example 1.6 and 1.9, for example between 1.7 and 1.8. The carrier material may, for example, include a solution-processed organic semiconductor material. The carrier material may, for example, include a polymer or soluble small molecules. The carrier material may include or be formed from one or more of the following materials: NET-18; 2,2′,2″-(1,3,5-benzinetriyl)-tris(1-phenyl-1-H-benzimidazole); 2-(4-biphenylyl)-5-(4-tert-butylphenyl)-1,3,4-oxadiazole-2,9-dimethyl-4,7-diphenyl-1,10-phenanthroline (BCP); 8-hydroxyquinolinolato-lithium, 4-(naphthalen-1-yl)-3,5-diphenyl-4H-1,2,4-triazole; 1,3-bis[2-(2,2′-bipyridine-6-yl)-1,3,4-oxadiazo-5-yl]benzene; 4,7-diphenyl-1,10-phenanthroline (BPhen); 3-(4-biphenylyl)-4-phenyl-5-tert-butylphenyl-1,2,4-triazole; bis(2-methyl-8-quinolinolate)-4-(phenylphenolato)aluminum; 6,6′-bis[5-(biphenyl-4-yl)-1,3,4-oxadiazo-2-yl]-2,2′-bipyridyl; 2-phenyl-9,10-di(naphthalen-2-yl)-anthracene; 2,7-bis[2-(2,2′-bipyridine-6-yl)-1,3,4-oxadiazo-5-yl]-9,9-dimethylfluorene; 1,3-bis[2-(4-tert-butylphenyl)-1,3,4-oxadiazo-5-yl]benzene; 2-(naphthalen-2-yl)-4,7-diphenyl-1,10-phenanthroline; 2,9-bis(naphthalen-2-yl)-4,7-diphenyl-1,10-phenanthroline; tris(2,4,6-trimethyl-3-(pyridin-3-yl)phenyl)borane; 1-methyl-2-(4-(naphthalen-2-yl)phenyl)-1H-imidazo[4,5-f][1,10]phenanthroline; phenyl-dipyrenylphosphine oxides; naphthalenetetracarboxylic dianhydride or imides thereof; perylenetetracarboxylic dianhydride or imides thereof; and substances based on siloles having a silacyclopentadiene unit.

The nano-additives include, for example, nanoparticles, nanowires, nanodots and/or nanotubes. The nano-additives may have a second refractive index which is greater than the first refractive index. The second refractive index may lie in a range of, for example, from 2.1 to 2.5. The nano-additives have at least one external dimension which is less than one fourth of a predetermined wavelength of the light generated. The external dimension may, for example, be a diameter and/or a side length. The predetermined wavelength may, for example, be a dominant wavelength of the light generated. For example, the predetermined wavelength may be a shortest dominant wavelength or a longest dominant wavelength of the light generated. The predetermined wavelength may for example lie in the visible spectral range, for example in the range of from approximately 380 nm to approximately 780 nm, for example in the green spectral range of from approximately 480 nm to approximately 560 nm, for example approximately 555 nm, or for example in the blue spectral range of from approximately 420 nm to approximately 480 nm, for example approximately 460 nm.

As an alternative or in addition, the external dimension may be less than a thickness of the electron transport layer 44. For example, the thickness may lie in a range of for example between 0.1 and 20 nm, for example between 1 nm and 10 nm. The nano-additives may for example include TiO₂, Nb₂O₅, HfO₂, ZrO₂, and/or ZnS.

The electron transport layer 44 may have a layer thickness in a range of from approximately 5 nm to approximately 50 nm, for example in a range of from approximately 10 nm to approximately 30 nm, for example approximately 20 nm.

The electron injection layer may be formed on or over the electron transport layer 44. The electron injection layer may include or be formed from one or more of the following materials: NDN-26, MgAg, Cs₂CO₃, Cs₃PO₄, Na, Ca, K, Mg, Cs, Li, LiF; 2,2′,2″-(1,3,5-benzinetriyl)-tris(1-phenyl-1-H-benzimidazole); 2-(4-biphenylyl)-5-(4-tert-butylphenyl)-1,3,4-oxadiazole,2,9-dimethyl-4,7-diphenyl-1,10-phenanthroline (BCP); 8-hydroxyquinolinolato-lithium, 4-(naphthalen-1-yl)-3,5-diphenyl-4H-1,2,4-triazole; 1,3-bis[2-(2,2′-bipyridine-6-yl)-1,3,4-oxadiazo-5-yl]benzene; 4,7-diphenyl-1,10-phenanthroline (BPhen); 3-(4-biphenylyl)-4-phenyl-5-tert-butylphenyl-1,2,4-triazole; bis(2-methyl-8-quinolinolate)-4-(phenylphenolato)aluminum; 6,6′-bis[5-(biphenyl-4-yl)-1,3,4-oxadiazo-2-yl]-2,2′-bipyridyl; 2-phenyl-9,10-di(naphthalen-2-yl)-anthracene; 2,7-bis[2-(2,2′-bipyridine-6-yl)-1,3,4-oxadiazo-5-yl]-9,9-dimethylfluorene; 1,3-bis[2-(4-tert-butylphenyl)-1,3,4-oxadiazo-5-yl]benzene; 2-(naphthalen-2-yl)-4,7-diphenyl-1,10-phenanthroline; 2,9-bis(naphthalen-2-yl)-4,7-diphenyl-1,10-phenanthroline; tris(2,4,6-trimethyl-3-(pyridin-3-yl)phenyl)borane; 1-methyl-2-(4-(naphthalen-2-yl)phenyl)-1H-imidazo[4,5-f][1,10]phenanthroline; phenyl-dipyrenylphosphine oxides; naphthalenetetracarboxylic dianhydride or imides thereof; perylenetetracarboxylic dianhydride or imides thereof; and substances based on siloles having a silacyclopentadiene unit.

The electron injection layer may have a layer thickness in a range of from approximately 5 nm to approximately 200 nm, for example in a range of from approximately 20 nm to approximately 50 nm, for example approximately 30 nm.

In the case of an organic functional layer structure 22 having two or more organic functional layer structure units, corresponding intermediate layers may be formed between the organic functional layer structure units. The organic functional layer structure units may respectively be configured individually per se according to one configuration of the organic functional layer structure 22 explained above. The intermediate layer may be configured as an intermediate electrode. The intermediate electrode may be electrically connected to an external voltage source. The external voltage source may, for example, provide a third electrical potential to the intermediate electrode. The intermediate electrode may also, however, not include an external electrical terminal, for example with the intermediate electrode having a floating electrical potential.

The organic functional layer structure unit may for example have a layer thickness of at most approximately 3 μm, for example a layer thickness of at most approximately 1 μm, for example a layer thickness of at most approximately 300 nm.

The organic light-emitting component 10 may optionally include further functional layers, for example arranged on or over the one or more emitter layers or on or over the electron transport layer 44. The further functional layers may for example be internal or external output coupling structures, which may further improve the functionality and therefore the efficiency of the organic light-emitting component 10.

The second electrode 23 may be configured according to one of the configurations of the first electrode 20, in which case the first electrode 20 and the second electrode 23 may be configured identically or differently. The second electrode 23 may be configured as an anode or as a cathode. The second electrode 23 may have a second electrical terminal, to which a second electrical potential can be applied. The second electrical potential may be provided by the same energy source or a different energy source to the first electrical potential. The second electrical potential may be different to the first electrical potential. The second electrical potential may, for example, have a value such that the difference from the first electrical potential has a value in a range of from approximately 1.5 V to approximately 20 V, for example a value in a range of from approximately 2.5 V to approximately 15 V, for example a value in a range of from approximately 3 V to approximately 12 V.

The encapsulation layer 24 may also be referred to as thin-film encapsulation. The encapsulation layer 24 may be configured as a translucent or transparent layer. The encapsulation layer 24 forms a barrier against chemical contaminations or atmospheric substances, in particular against water (moisture) and oxygen. In other words, the encapsulation layer 24 is configured in such a way that it cannot be penetrated, or can be penetrated at most in very small amounts, by substances that can damage the organic light-emitting component 10, for example water, oxygen or solvent. The encapsulation layer 24 may be configured as a single layer, a layer stack or a layer structure.

The encapsulation layer 24 may include or be formed from: aluminum oxide, zinc oxide, zirconium oxide, titanium oxide, hafnium oxide, tantalum oxide, lanthanum oxide, silicon oxide, silicon nitride, silicon oxynitride, indium tin oxide, indium zinc oxide, aluminum-doped zinc oxide, poly(p-phenylene terephthalamide), nylon 66, as well as mixtures and alloys thereof.

The encapsulation layer 24 may have a layer thickness of from approximately 0.1 nm (one atomic layer) to approximately 1000 nm, for example a layer thickness of from approximately 10 nm to approximately 100 nm, for example approximately 40 nm. The encapsulation layer 24 may include a high-index material, for example one or more materials having a high refractive index, for example having a refractive index of from 1.5 to 3, for example from 1.7 to 2.5, for example from 1.8 to 2.

Optionally, the first barrier layer on the carrier 12 may be configured according to one configuration of the encapsulation layer 24.

The encapsulation layer 24 may for example be formed by means of a suitable deposition method, for example by means of an atomic layer deposition (ALD) method, for example a plasma enhanced atomic layer deposition (PEALD) method or a plasma-less atomic layer deposition (PLALD) method, or by means of a chemical vapor deposition (CVD) method, for example a plasma enhanced chemical vapor deposition (PECVD) method or a plasma-less chemical vapor deposition (PLCVD) method, or alternatively by means of other suitable deposition methods.

Optionally, an input or output coupling layer may be configured, for example, as an external film (not represented) on the carrier 12 or as an internal output coupling layer (not represented) in the layer cross section of the organic light-emitting component 10. The input/output coupling layer may include a matrix and scattering centers distributed therein, the average refractive index of the input/output coupling layer being greater than the average refractive index of the layer from which the light is provided. Furthermore, one or more antireflection layers may additionally be formed.

The bonding layer 36 may for example include a bonding agent, for example adhesive, for example a laminating adhesive, and/or a coating and/or a resin, by means of which the cover body 38 is arranged, for example adhesively bonded, for example on the encapsulation layer 24. The bonding layer 36 may be configured so as to be transparent or translucent. The bonding layer 36 may, for example, include light-scattering particles. In this way, the bonding layer 36 can act as a scattering layer and contribute to a good hue distortion and a high output coupling efficiency.

As light-scattering particles, it is possible to provide dielectric scattering particles, for example consisting of a metal oxide, for example silicon oxide (SiO₂), zinc oxide (ZnO), zirconium oxide (ZrO₂), indium tin oxide (ITO) or indium zinc oxide (IZO), gallium oxide (Ga₂Oₓ) aluminum oxide or titanium oxide. Other particles may also be suitable, so long as they have a refractive index different to the effective refractive index of the matrix of the bonding layer 36, for example air bubbles, acrylate or hollow glass spheres. Furthermore, metallic nanoparticles, metals such as gold, silver, iron nanoparticles, or the like may for example be provided as light-scattering particles.

The bonding layer 36 may have a layer thickness of more than 1 μm, for example a layer thickness of several μm. In various embodiments, the adhesive may be a lamination adhesive.

The bonding layer 36 may have a refractive index which is less than the refractive index of the cover body 38. The bonding layer 36 may for example include a low-index adhesive, for example an acrylate, which has a refractive index of approximately 1.3. The bonding layer 36 may, however, also include a high-index adhesive, which for example includes high-index nonscattering particles and has a layer thickness-averaged refractive index which corresponds approximately to the average refractive index of the organically functional layer structure 22, for example in a range of from approximately 1.6 to 2.5, for example from 1.7 to approximately 2.0.

A so-called getter layer or getter structure, i.e. a laterally structured getter layer, (not represented) may be arranged on or over the active region. The getter layer may be configured so as to be translucent, transparent or opaque. The getter layer may include or be formed from a material which absorbs and binds substances that are harmful for the active region. A getter layer may, for example, include or be formed from a zeolite derivative. The getter layer may have a layer thickness of more than 1 μm, for example a layer thickness of several μm. In various embodiments, the getter layer may include a lamination adhesive or be embedded in the bonding layer 36.

The cover body 38 may for example be formed by a glass body, a metal foil or a sealed plastic film cover body. The cover body 38 may, for example, be arranged by means of frit bonding (glass frit bonding/glass soldering/seal glass bonding) by means of a conventional glass solder in the geometrical edge regions of the organic light-emitting component 10 on the encapsulation layer 24, or the active region. The cover body 38 may, for example, have a refractive index (for example at a wavelength of 633 nm) of for example from 1.3 to 3, for example from 1.4 to 2, for example from 1.5 to 1.8.

The cover body 38 includes, for example, glass and/or metal. For example, the cover body 38 may be formed essentially from glass and include a thin metal layer, for example a metal foil, and/or a graphite layer, for example a graphite laminate, on the glass body. The cover body 38 is used to protect the organic light-emitting component 10, for example, against the effects of mechanical force from the outside. Furthermore, the cover body 38 may be used to distribute and/or dissipate heat which is generated in the organic light-emitting component 10. For example, the glass of the cover body 38 may be used as protection against external influences, and the metal layer of the cover body 38 may be used to distribute and/or dissipate the heat given off during operation of the organic light-emitting component 10.

FIG. 4 shows an embodiment of an organic light-emitting component 10, which may for example correspond substantially to the organic light-emitting component 10 above.

As an alternative or in addition to the nano-additives in the electron transport layer 44, the nano-additives are arranged in the emitter layer 42. The above-explained material of the emitter layer 42 is used as a carrier material for the nano-additives. The nano-additives may be configured according to one configuration of the nano-additives explained above. The nano-additives and the carrier material of the emitter layer 42 may be configured according to the nano-additives and/or the carrier material of the electron transport layer 44 over the hole transport layer 40, for example in the form of a liquid solution.

If nano-additives are arranged in the electron transport layer 44 and in the emitter layer 42, then the nano-additives in the electron transport layer 44 may be configured identically or differently to the nano-additives in the emitter layer 42.

FIG. 5 shows an embodiment of an organic light-emitting component 10, which may for example correspond substantially to the organic light-emitting component 10 above.

As an alternative or in addition to the nano-additives in the electron transport layer 44 and/or the emitter layer 42, the nano-additives are arranged in the hole transport layer 40. The above-explained material of the hole transport layer 40 is used as a carrier material for the nano-additives. The nano-additives may be configured according to one configuration of the nano-additives explained above. The nano-additives and the carrier material of the hole transport layer 40 may be configured according to the nano-additives and/or the carrier material of the electron transport layer 44 and/or of the emitter layer 42 over the first electrode 20, for example in the form of a liquid solution.

If nano-additives are arranged in the electron transport layer 44 and in the hole transport layer 40, and/or in the emitter layer 42 and in the hole transport layer 40, then the nano-additives in the hole transport layer 40 may be configured identically or differently to the nano-additives in the emitter layer 42 and/or the electron transport layer 44.

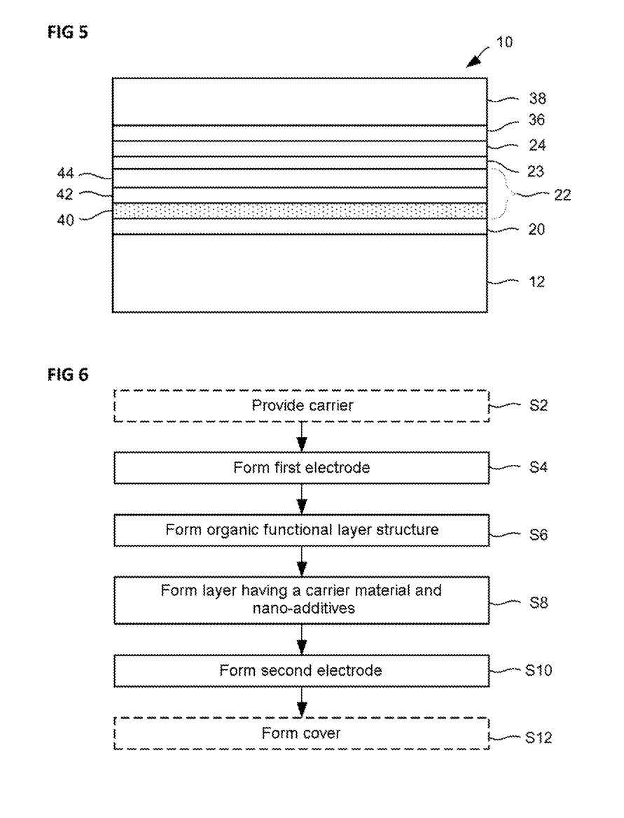

FIG. 6 shows a flowchart of an embodiment of a method for producing an organic light-emitting component, for example the light-emitting component 10 explained above.

In a step S2, a carrier is provided, for example the carrier 12 explained above. The carrier 12 may, for example, be formed.

In a step S4, a first electrode is formed, the first electrode 20 being formed for example over the carrier 12. The first electrode 20 may for example be deposited over the carrier 12, and optionally over the barrier layer on the carrier 12.

In a step S6, an organic functional layer structure is formed, the organic functional layer structure 22 being formed for example over the first electrode 20.

In a step S8, a layer of the organic functional layer structure 22 is configured in the form of the carrier material including the nano-additives. The step S8 is carried out in the course of carrying out step S6. In other words, step S8 is a substep of step S6. The layer including the nano-additives may be the hole transport layer 40, the hole injection layer, the emitter layer 42, the electron transport layer 44 and/or the electron injection layer.

A concentration of the nano-additives in the carrier material, a number of nano-additives in the carrier material and/or the nano-additives per se are, for example while taking into account their refractive index and/or a thickness of the corresponding layer, predetermined as a function of the optical property to be predetermined, for example the optical path length from the emitter layer 42 to the first and/or second electrode 20, 23. In particular, with the aid of the nano-additives, the refractive index of the carrier material is shifted toward an overall refractive index of the layer of carrier material and nano-additives in such a way that the corresponding layer contributes to the predetermined optical property being achieved. The optical path length between an emission zone and one of the electrodes 20, 23 may, for example, be from approximately 80 nm to approximately 800 nm, for example from approximately 200 nm to approximately 600 nm, for example approximately 400 nm.

As the carrier material, it is for example possible to use an organic semiconductor that can be processed in the form of a liquid solution, for example a polymer or soluble small molecules. In this case, the nano-additives may be applied from solution together with the organic material. For better processability, it is furthermore possible to use nano-additives which have corresponding surface functionalization that allows them to be soluble in the selected solvent and/or carrier material.

In a step S10, a second electrode is formed, the second electrode 23 being formed for example over the organic functional layer structure 22. For example, the second electrode 23 may be deposited over the organic functional layer structure 22.

Optionally, a cover may be formed in a step S12. For example, the cover may be formed over the second electrode 23. The cover may for example include the encapsulation layer 24, the bonding layer 36 and/or the cover body 38.

The disclosure is not restricted to the embodiments indicated. For example, the nano-additives may be arranged in any desired layer of the organic functional layer structure 22. Furthermore, the organic light-emitting component 10 may include further layers, for example output coupling layers or light-shaping layers, which may be formed in corresponding further steps of the method explained above.

While the disclosed embodiments have been particularly shown and described with reference to specific embodiments, it should be understood by those skilled in the art that various changes in form and detail may be made therein without departing from the spirit and scope of the disclosed embodiments as defined by the appended claims. The scope of the disclosed embodiments is thus indicated by the appended claims and all changes which come within the meaning and range of equivalency of the claims are therefore intended to be embraced.

1. An organic light-emitting component, comprising:
a first electrode,
an organic functional layer structure over the first electrode in order to generate light, and
a second electrode over the organic functional layer structure, wherein the organic functional layer structure comprises at least one layer having an organic carrier material, which has a first refractive index, and having nano-additives which are embedded in the carrier material and have a second refractive index, which is greater than the first refractive index, and which have at least one external dimension which is less than one fourth of a predetermined wavelength of the light generated,
wherein the nano-additives, the material of the nano-additives and/or a fraction of the nano-additives relative to the carrier material of the layer are selected and/or predetermined as a function of an optical path length in the organic light-emitting component or as a function of a size of a microcavity of the organic light-emitting component.

2. The organic light-emitting component as claimed in claim 1, wherein the predetermined wavelength is a dominant wavelength of the light generated.

3. The organic light-emitting component as claimed in claim 2, wherein the predetermined wavelength is a shortest dominant wavelength or a longest dominant wavelength of the light generated.

4. The organic light-emitting component as claimed in claim 1, wherein the nano-additives comprise nanoparticles, nanowires, nanodots and/or nanotubes.

5. The organic light-emitting component as claimed in claim 1, wherein the first refractive index lies in a range of between 1.6 and 1.8, and/or wherein the second refractive index lies in a range of between 2.1 and 2.5.

6. The organic light-emitting component as claimed in claim 1, wherein the nano-additives comprise TiO₂, HfO₂, ZrO₂, Nb₂O₅ and/or ZnS.

7. The organic light-emitting component as claimed in claim 1, wherein the carrier material comprises a solution-processed organic semiconductor material.

8. The organic light-emitting component as claimed in claim 1, wherein the carrier material comprises a polymer or soluble small molecules.

9. The organic light-emitting component as claimed in claim 1, wherein a hole injection layer, a hole transport layer, an electron injection layer, an electron transport layer and/or an emitter layer of the organic functional layer structure comprises or is formed from the layer having the carrier material and the nano-additives.

10. A method for producing an organic light-emitting component, the method comprising:
forming a first electrode,
forming an organic functional layer structure over the first electrode in order to generate light, and
forming a second electrode over the organic functional layer structure,
wherein the organic functional layer structure is formed in such a way that it comprises at least one layer having an organic carrier material, which has a first refractive index, and having nano-additives which are embedded in the carrier material and have a second refractive index, which is greater than the first refractive index, and which have at least one external dimension which is less than one fourth of a predetermined wavelength of the light generated,
wherein the nano-additives, the material of the nano-additives and/or a fraction of the nano-additives relative to the carrier material of the layer are selected and/or predetermined as a function of an optical path length in the organic light-emitting component or as a function of a size of a microcavity of the organic light-emitting component.

11. The method as claimed in claim 10, wherein the carrier material is applied in the liquid state onto the first electrode, the nano-additives being dissolved or dispersed in the liquid carrier material.

12. The method as claimed in claim 10, wherein the optical path length is the optical path length from an emission zone of the organic functional layer structure to one of the electrodes.

13. An organic light-emitting component, comprising:
a first electrode,
an organic functional layer structure over the first electrode in order to generate light, and
a second electrode over the organic functional layer structure,
wherein the organic functional layer structure comprises at least one layer having an organic carrier material, which has a first refractive index, and having nano-additives which are embedded in the carrier material and have a second refractive index, which is greater than the first refractive index, and which have at least one external dimension which is less than one fourth of a predetermined wavelength of the light generated,
wherein the first electrode and the second electrode are mirrors of a microcavity, and
wherein the nano-additives, the material of the nano-additives and/or a fraction of the nano-additives relative to the carrier material of the layer are selected and/or predetermined depending of a size of the microcavity such that the microcavity is resonant for the predetermined wavelength.

14. The organic light-emitting component as claimed in claim 13, wherein the predetermined wavelength is a dominant wavelength of the light generated.

15. The organic light-emitting component as claimed in claim 14, wherein the predetermined wavelength is a shortest dominant wavelength or a longest dominant wavelength of the light generated.

16. The organic light-emitting component as claimed in claim 13, wherein the nano-additives comprise nanoparticles, nanowires, nanodots and/or nanotubes.
